(19) United States
(12) Patent Application Publication
(10) Pub. No.: US 2018/0363129 A1
(43) Pub. Date: Dec. 20, 2018

(54) Evaporation Apparatus

(71) Applicant: BOE Technology Group Co., Ltd., Beijing (CN)

(72) Inventors: Shupeng Guo, Beijing (CN); Changqi Hu, Beijing (CN)

(73) Assignees: BOE Technology Group Co., Ltd., Beijing (CN); BOE Technology Group Co., Ltd., Beijing (CN); Hefei Xinsheng Optoelectronics Technology Co., Ltd., Hefei City (CN); Hefei Xinsheng Optoelectronics Technology Co., Ltd., Hefei City (CN)

(21) Appl. No.: 15/781,957

(22) PCT Filed: Dec. 15, 2017
(86) PCT No.: PCT/CN2017/116463

§ 371 Date: Jun. 6, 2018

(30) Foreign Application Priority Data
May 22, 2017 (CN) 201720572004.6

(51) Int. Cl. C23C 14/54; C23C 16/455; C23C 16/52; G01B 7/06; C23C 14/24

(52) U.S. Cl. CPC C23C 14/544; C23C 16/455; C23C 14/243; G01B 7/066; C23C 16/52

(57) ABSTRACT

An evaporation apparatus is disclosed. The evaporation apparatus includes an operation platform; an evaporation source on the operation platform; an inner plate on at least one side of the evaporation source, the inner plate being fixedly connected to the evaporation source; and an outer plate on a side of the inner plate away from the evaporation source, the outer plate being adjacent to the inner plate. The inner plate can be configured to detect an evaporation rate of the evaporation source, and the outer plate can adjust an evaporation range.

The application claims priority of Chinese patent application No. 201720572004.6 filed with the SIPO on May 22, 2017, the entire disclosure of which is incorporated herein by reference as part of the present application.

### TECHNICAL FIELD

Embodiments of the present disclosure relate to an evaporation apparatus.

### BACKGROUND

With the development of display technology, organic light-emitting diode (OLED) display has gained attentions, increasingly, for its advantageous such as self-luminance, wide viewing angle, high resolution ratio, low power consumption and quick reaction speed.

The OLED is a light-emitting element including a plurality of types of functional layers which are stacked one on another. Currently, a manufacturing method of the OLED includes an evaporation process. That is, the functional layer of the OLED, e.g., an organic light-emitting layer, is evaporated by utilizing the evaporation process.

### SUMMARY

An embodiment of the present disclosure provides an evaporation apparatus. The evaporation apparatus includes an evaporation source, an inner plate, an outer plate and a driving device. The evaporation source includes at least one evaporation hole; the inner plate is located at two sides of the evaporation hole; the outer plate is disposed at a side of the inner plate away from the evaporation hole; the driving device is connected to the outer plate, and is configured to drive the outer plate so as to adjust an evaporation range. At least one embodiment of the present disclosure provides an evaporation apparatus, including an operation platform; an evaporation source on the operation platform; an inner plate on at least one side of the evaporation source, the inner plate being configured to detect an evaporation rate of the evaporation source and fixedly connected to the evaporation source; an outer plate on a side of the inner plate away from the evaporation source, the outer plate being configured to adjust an evaporation range.

For example, in the evaporation apparatus provided by an embodiment of the present disclosure, the inner plate and the outer plate are at two opposite sides of the evaporation source, respectively.

For example, the evaporation apparatus provided by an embodiment of the present disclosure further includes a driving device; the driving device is connected to the outer plate and is configured to drive the outer plate to adjust the evaporation range.

For example, in the evaporation apparatus provided by an embodiment of the present disclosure, the driving device includes a lifting device; the lifting device is configured to drive the outer plate to move in a direction away from the operation platform so as to change a height of the outer plate with respect to the operation platform.

For example, in the evaporation apparatus provided by an embodiment of the present disclosure, the driving device includes a lifting device; the lifting device is configured to drive the outer plate to move in a direction away from the operation platform.

For example, in the evaporation apparatus provided by an embodiment of the present disclosure, the driving device includes a rotating device; the outer plate includes: a main body part at a side of the inner plate away from the evaporation source, the main body and the inner plate both extend along a direction perpendicular to the operation platform, an end of the main body part away from the evaporation source extends beyond an end of the inner plate away from the evaporation source; and a rotating part, an end of the rotating part is hinged with the end of the main body part away from the evaporation source, the rotating device is configured to drive the rotating part to rotate towards a direction close to the evaporation source and a direction away from the evaporation source.

For example, the evaporation apparatus provided by an embodiment of the present disclosure further includes a film thickness detector; the film thickness detector is at least partly disposed inside the inner plate and is configured to detect an evaporation rate of the evaporation apparatus.

For example, in the evaporation apparatus provided by an embodiment of the present disclosure, the film thickness detector includes a piezoelectric sensor.

For example, the evaporation apparatus provided by an embodiment of the present disclosure further includes a controller; the controller is communicatively connected to the film thickness detector and the driving device, respectively, and is configured to control the driving device according to an evaporation rate detected by the film thickness detector.

For example, the evaporation apparatus provided by an embodiment of the present disclosure further includes a cooling device; the cooling device is disposed inside the inner plate and is configured to cool the film thickness detector.

For example, in the evaporation apparatus provided by an embodiment of the present disclosure, the cooling device includes a cooling liquid pipeline.

For example, the evaporation apparatus provided by an embodiment of the present disclosure further includes an electrical circuit; the electrical circuit is disposed inside the inner plate and is connected to the film thickness detector.

For example, in the evaporation apparatus provided by an embodiment of the present disclosure, the electrical circuit includes at least one of a power supply line and a signal transmission line.

For example, in the evaporation apparatus provided by an embodiment of the present disclosure, a first surface of the inner plate facing the outer plate is disposed to be in contact with a second surface of the outer plate facing the inner plate.

For example, in the evaporation apparatus provided by an embodiment of the present disclosure, an end of the inner plate away from the evaporation source includes a first inclined surface biased to a side of the inner plate close to the evaporation source.

For example, in the evaporation apparatus provided by an embodiment of the present disclosure, an end of the outer plate away from the evaporation source includes a second inclined surface biased to a side of the outer plate close to the evaporation source.

For example, in the evaporation apparatus provided by an embodiment of the present disclosure, the evaporation source includes a plurality of evaporation holes, the plurality of evaporation holes are arranged in a line on the evaporation source.

For example, in the evaporation apparatus provided by an embodiment of the present disclosure, the evaporation source includes a plurality of evaporation holes, the plurality of evaporation holes are arranged in a line on the evaporation source; the evaporation apparatus includes a plurality of film thickness detectors, the plurality of film thickness detectors are disposed in one-to-one correspondence with the plurality of evaporation holes.

### BRIEF DESCRIPTION OF THE DRAWINGS

Hereinafter, in order to clearly describe technical solutions of the embodiments in the present disclosure in a better way, the drawings of the embodiments will be briefly introduced. Obviously, the drawings to be described below merely relate to some embodiments of the present disclosure without any limitation to the present disclosure.

FIG. 1 is a structural diagram of an evaporation apparatus provided by an embodiment of the present disclosure;

FIG. 2 is a working principle diagram of an evaporation apparatus provided by an embodiment of the present disclosure;

FIG. 3 is an perspective schematic view of an evaporation apparatus provided by an embodiment of the present disclosure;

FIG. 4 is a structural diagram of another evaporation apparatus provided by an embodiment of the present disclosure;

FIG. 5 is a working principle diagram of another evaporation apparatus provided by an embodiment of the present disclosure; and

FIG. 6 is a schematic diagram illustrating a connecting relationship of a controller in an evaporation apparatus provided by an embodiment of the present disclosure.

### DETAILED DESCRIPTION

Hereinafter, the technical solutions in the embodiments of the present disclosure will be clearly, completely described with reference to the drawings in the embodiments of the present disclosure. Obviously, the embodiments described are only a part of the embodiments, not all embodiments. Based on the embodiments in the present disclosure, all other embodiments obtained by one skilled in the art without paying inventive labor are within the protection scope of the present disclosure.

Unless otherwise defined, all the technical and scientific terms used herein have the same meanings as commonly understood by one of ordinary skill in the art to which the present invention belongs. The terms “first,” “second,” etc., which are used in the present disclosure, are not intended to indicate any sequence, amount or importance, but distinguish various components. The phrases “comprise(s)” and “include(s)” etc., refer to that, an element or an object preceding this phrase encompasses element(s) or object(s) listed following this phrase, and equivalents thereof, without excluding the existence of other element(s) or object(s). The phrases “connect”, “connected”, etc., are not intended to define a physical connection or mechanical connection, but may include an electrical connection, directly or indirectly.

In study, inventors of the present application found that, in order to improve a performance of the OLED such as a capability of injecting and transmitting carriers, a luminous efficiency and a device lifetime, and also to manufacture OLED devices with different properties, it needs to adjust thicknesses of different functional layers in the OLED. Generally, a method of raising and lowering a temperature is adopted to change an evaporation rate of the evaporation source, so as to adjust a thickness of the functional layer to be formed. However, raising and lowering the temperature cost a relatively longer time, which may result in huge losses. Moreover, in an ordinary evaporation apparatus, electrical circuits such as signal transmission lines and control lines are all arranged as exposed lines, and involve problems such as a damage resulted by baking under high temperature and a sticking of evaporated material.

An embodiment of the present disclosure provides an evaporation apparatus. The evaporation apparatus includes an operation platform; an evaporation source on the operation platform; an inner plate; and an outer plate. The inner plate is on at least one side of the evaporation source, configured to be able to detect an evaporation rate of the evaporation source, and fixedly connected to the evaporation source. The outer plate is on a side of the inner plate away from the evaporation source and is adjacent to the inner plate; the outer plate is able to adjust an evaporation range. In this way, the evaporation apparatus can adjust an evaporation rate of the evaporation apparatus by adjusting the evaporation range of the evaporation source, so as to adjust a thickness of a film layer to be formed by evaporation, thereby achieving a quick adjustment of the thickness of the film layer to be formed by evaporation and improving a production efficiency.

Hereinafter the evaporation apparatus provided by the embodiments of the present disclosure will be described in conjunction with the drawings.

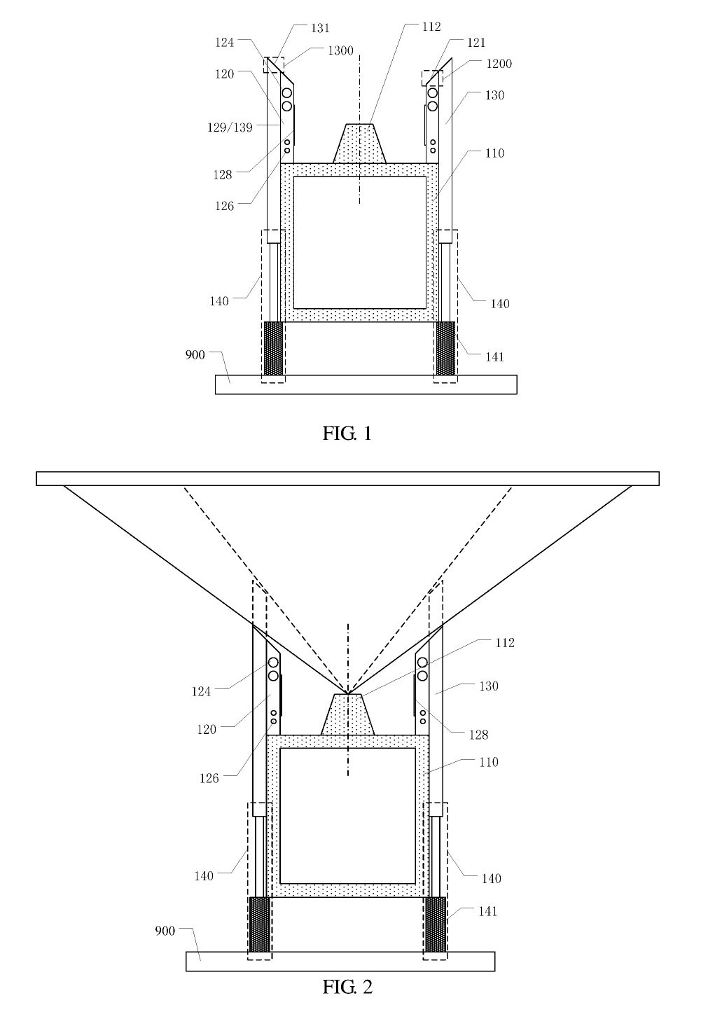

An embodiment of the present disclosure provides an evaporation apparatus. FIG. 1 is a structural diagram of an evaporation apparatus provided by an embodiment of the present disclosure. As illustrated in FIG. 1, the evaporation apparatus includes: an operation platform 900, an evaporation source 110 on the operation platform 900, an inner plate 120 and an outer plate 130. The inner plate 120 is on at least one side of the evaporation source 110, can detect an evaporation rate of the evaporation source 110, and is fixedly connected to the evaporation source 110. The outer plate 130 is on a side of the inner plate 120 away from the evaporation source 110 and is adjacent to the inner plate 120; the outer plate 130 can adjust an evaporation range.

In the evaporation apparatus provided by the embodiment of the present disclosure, the outer plate can limit the evaporation range of the evaporation source, e.g., the outer plate can move in a direction perpendicular to the operation platform, so as to change the evaporation range of the evaporation source. For example, given a same amount of evaporation material, when the evaporation range of the evaporation source is expanded, the evaporation material would be evaporated over a larger range, resulting in a reduced evaporation rate of the evaporation apparatus; when the evaporation range of the evaporation source is narrowed, the evaporation material would be evaporated over a smaller range, resulting in an increased evaporation rate of the evaporation apparatus. In this way, the evaporation apparatus can adjust the evaporation range of the evaporation source by driving the outer plate through the driving device, so as to be able to adjust the evaporation rate of the evaporation apparatus. By adjusting the evaporation rate of the evaporation apparatus, the thickness of the film layer to be formed by evaporation can be adjusted, so as to achieve quick adjustment of the thickness of the film layer to be formed by evaporation, thereby improving the production efficiency. It should be explained that, the evaporation rate mentioned above refers to an amount of evaporation material deposited on a unit area within a unit time period by the evaporation apparatus.

For example, in the evaporation apparatus provided by an embodiment of the present disclosure, as illustrated in FIG. 1, the inner plate 120 and the outer plate 130 are at two opposite sides of the evaporation source 110, respectively, so as to limit the evaporation range at two opposite sides of the evaporation source 110.

For example, in the evaporation apparatus provided by an embodiment of the present disclosure, as illustrated in FIG. 1, the evaporation apparatus further includes a driving device 140; the driving device 140 is connected to the outer plate 130 and can drive the outer plate 130 to adjust the evaporation range.

For example, in some examples, as illustrated in FIG. 1, the evaporation apparatus includes: an evaporation source 110, an inner plate 120, an outer plate 130 and a driving device 140. The evaporation source 110 includes at least one evaporation hole 112; an evaporation material can be heated in the evaporation source 110 and can be evaporated to leave through the evaporation hole 112; the inner plate 130 is disposed on the evaporation source 110 and located at both sides of the evaporation hole 112; the outer plate 130 is disposed at a side of the inner plate 120 away from the evaporation hole 112, that is, the outer plate 130 is disposed at an outside of the inner plate 120; the driving device 140 is connected to the outer plate 130, and the driving device 140 can drive the outer plate 130 to adjust the evaporation range. That is to say, the outer plate 130 can limit the evaporation range of the evaporation source 110, and the driving device 140 can be utilized to adjust the evaporation range of the evaporation source 110.

In the evaporation apparatus provided by the embodiment of the present disclosure, the outer plate can limit the evaporation range of the evaporation source, e.g., the outer plate can move in a direction perpendicular to the operation platform, so as to change the evaporation range of the evaporation source. For example, given a same amount of evaporation material, when the evaporation range of the evaporation source is expanded, the evaporation material would be evaporated over a larger range, resulting in a reduced evaporation rate of the evaporation apparatus; when the evaporation range of the evaporation source is narrowed, the evaporation material would be evaporated over a smaller range, resulting in an increased evaporation rate of the evaporation apparatus. In this way, the evaporation apparatus can adjust the evaporation range of the evaporation source by driving the outer plate through the driving device, so as to be able to adjust the evaporation rate of the evaporation apparatus. By adjusting the evaporation rate of the evaporation apparatus, the thickness of the film layer to be formed by evaporation can be adjusted, so as to achieve quick adjustment of the thickness of the film layer to be formed by evaporation, thereby improving the production efficiency. It should be explained that, the evaporation rate mentioned above refers to an amount of evaporation material deposited on a unit area within a unit time period by the evaporation apparatus.

For example, in the evaporation apparatus provided by the present embodiment, as illustrated in FIG. 1, the outer plate 120 and the inner plate 130 both extend along a direction parallel to a center line (as illustrated in FIG. 1) of the evaporation hole 112, an end of the outer plate 130 away from the evaporation source 110 extends beyond an end of the inner plate 120 away from the evaporation source 110, and the outer plate 130 can move along a direction parallel to the center line of the evaporation hole 112 with respect to the inner plate 120. In this way, the outer plate 130 can limit the evaporation range of the evaporation source 110; moreover, when the outer plate 130 moves along the direction parallel to the center line of the evaporation hole 112 with respect to the inner plate 120, the evaporation range of the evaporation source 110 can be changed. FIG. 2 is a working principle diagram of an evaporation apparatus provided by an embodiment of the present disclosure. As illustrated in FIG. 2, when the outer plate 130 moves upwards along the direction parallel to the center line of the evaporation hole 112 with respect to the inner plate 120 (the end of the outer plate 130 away from the evaporation source 110 is indicated by the dashed line in FIG. 2), in a plane illustrated in FIG. 2, an evaporation angle of the evaporation source 110 is decreased, that is, the evaporation range of the evaporation source 110 is narrowed. Similarly, when the outer plate 130 moves downwards along the direction parallel to the center line of the evaporation hole with respect to the inner plate 120, the evaporation range of the evaporation source is increased. In this way, the evaporation range of the evaporation source can be adjusted by moving the outer plate along the direction parallel to the center line of the evaporation hole with respect to the inner plate, so as to adjust the evaporation rate of the evaporation apparatus. Of course, the embodiments of the present disclosure include but not limited thereto, and the outer plate can adjust the evaporation range of the evaporation source by using other methods. It should be explained that, the direction parallel to the center line of the evaporation hole as illustrated in FIG. 1 is just the direction perpendicular to the operation platform.

For example, in the evaporation apparatus provided by an embodiment of the present disclosure, as illustrated in FIG. 1, the driving device 140 includes a lifting device 141; the lifting device 141 can drive the outer plate 140 to move along the direction parallel to the center line of the evaporation hole 112 so as to adjust a height of the outer plate 130 with respect to the operation platform 900. In this way, the outer plate can move along the direction parallel to the center line of the evaporation hole by the lifting device.

For example, the lifting device can include an air cylinder or a hydraulic device. Of course, the embodiments of the present disclosure include but not limited thereto, and the lifting device can also adopt other common structures, for example, the lifting device can realize ascending and descending movement by a lead screw and an electric motor.

For example, in the evaporation apparatus provided by an embodiment of the present disclosure, as illustrated in FIG. 1, the evaporation apparatus can further include a film thickness detector 128. The film thickness detector 128 is at least partly disposed inside the inner plate 120, and can be configured to detect the evaporation rate of the evaporation apparatus. In this way, the evaporation rate of the evaporation apparatus can be detected by means of the film thickness detector. Because an evaporation time of a substrate to be evaporated can be determined, when the evaporation apparatus is used for evaporating a film layer onto a substrate to be evaporated, a thickness of the evaporated film layer can be calculated based on the evaporation rate. That is to say, the thickness of the evaporated film layer evaporated on the substrate to be evaporated can be obtained by obtaining the evaporation rate of the evaporation apparatus. When it needs to adjust the thickness of the evaporated film layer evaporated on the substrate to be evaporated, the outer plate can be adjusted directly according to a current evaporation rate detected by the film thickness detector so as to change the evaporate rate. For example, it's possible to drive the outer plate, by the driving device, to move along the direction parallel to the center line of the evaporation hole, until the current evaporation rate detected by the film thickness detector equaling to a desired evaporation rate. Additionally, the film thickness detector is partly located inside the inner plate, thus a circuit for connecting the film thickness detector to the outside can be completely disposed inside the inner plate so as to prevent the circuit for connecting the film thickness detector to the outside from any damage resulted by baking under high temperature and sticking of evaporated material.

For example, the film thickness detector can include a piezoelectric sensor. In this way, the film thickness detector can determine the evaporation rate of the evaporation apparatus according to a weight of evaporation material deposited onto the piezoelectric sensor within a unit time period. Of course, the embodiments of the present disclosure include but not limited thereto, and the film thickness detector can also adopt other structures and sensors to realize the detection of the evaporation rate of the evaporation apparatus.

For example, in the evaporation apparatus provided by an embodiment of the present disclosure, as illustrated in FIG. 1, the evaporation apparatus can further include a cooling device 124; the cooling device 124 is disposed inside the inner plate 120 and is configured to cool the film thickness detector 128. In this way, by cooling the film thickness detector through the cooling device, on one hand, it avoids an excessively high temperature of the film thickness detector so as to improve a detecting precision of the film thickness detector, and on the other hand, it provides a protection to the film thickness detector so as to extend a service life of the film thickness detector.

For example, the cooling device includes a cooling liquid pipeline. The film thickness detector is cooled by circulating the cooling liquid. For example, the cooling liquid can be water. Of course, the embodiments of the present disclosure include but not limited thereto, and the film thickness detector can also be cooled by adopting forced air cooling and other methods.

For example, in the evaporation apparatus provided by an embodiment of the present disclosure, as illustrated in FIG. 1, the evaporation apparatus further includes an electrical circuit 126. The electrical circuit 126 is disposed inside the inner plate 120 and is connected with the film thickness detector 128. For example, the electrical circuit 126 can include a power supply line, a control line, a signal transmission line, etc. of the film thickness detector. In this way, when the electrical circuit is disposed inside the inner plate, the inner plate can provide the electrical circuit with protection function so as to prevent the electrical circuit from any damage resulted by baking under high temperature and sticking of evaporated material.

For example, in the evaporation apparatus provided by an embodiment of the present disclosure, as illustrated in FIG. 1, a first surface 129 of the inner plate 120 facing the outer plate 130 is disposed to be in contact with a second surface 139 of the outer plate 130 facing the inner plate 120. In this way, it can avoid the evaporation material deposited between the inner plate and the outer plate, so as to prevent the outer plate from moving with respect to the inner plate.

For example, in the evaporation apparatus provided by an embodiment of the present disclosure, as illustrated in FIG. 1, an end 1200 of the inner plate 120 away from the evaporation source 110 includes a first inclined surface 121 biased to a side of the inner plate 120 close to the evaporation hole 112, that is, the first inclined surface 121 is biased to a side of the inner plate 120 close to the evaporation source 110. In this way, it can prevent the evaporation material from heavily depositing on an end of the inner plate away from the evaporation source.

For example, in the evaporation apparatus provided by an embodiment of the present disclosure, as illustrated in FIG. 1, an end 1300 of the outer plate 130 away from the evaporation source 110 includes a second inclined surface 131 biased to a side of the outer plate 130 close to the evaporation hole 112, that is, the second inclined surface 131 is biased to a side of the outer plate 130 close to the evaporation source 110. In this way, it can prevent the evaporation material from heavily depositing on an end of the outer plate away from the evaporation source.

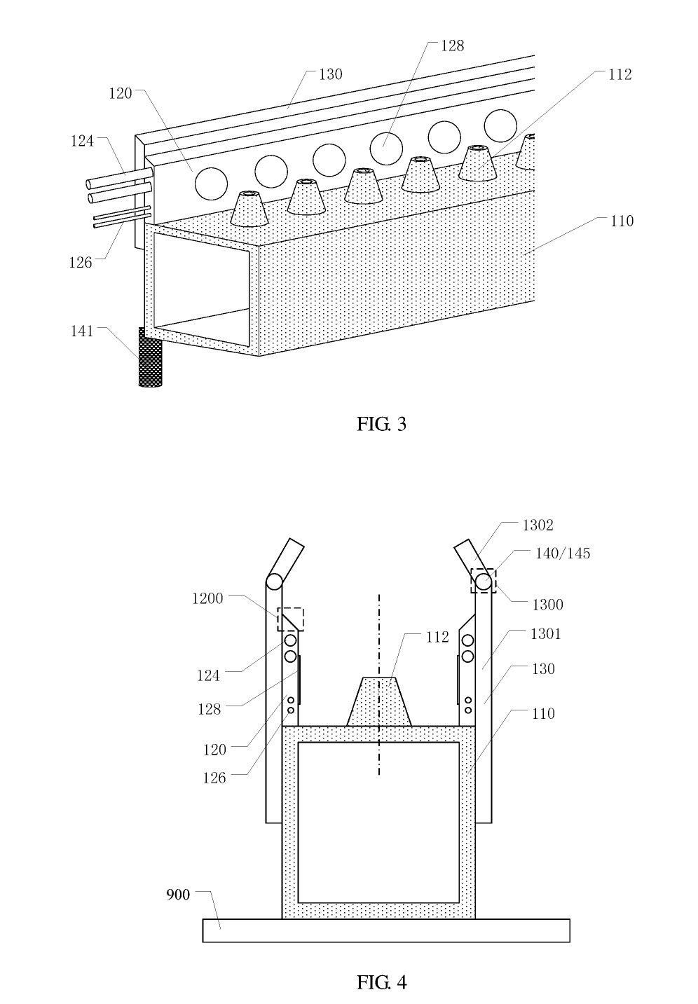

FIG. 3 is an elevation view of an evaporation apparatus provided by an embodiment of the present disclosure. As illustrated in FIG. 3, the evaporation apparatus includes an evaporation source 110, an inner plate 120, an outer plate 130 and a driving device 140. The evaporation source 110 includes at least one evaporation hole 112; an evaporation material can be heated in the evaporation source 110, and then evaporated to leave through the evaporation hole 112; the inner plate 130 is disposed on the evaporation source 110 and is located at both sides of the evaporation hole 112; the outer plate 130 is disposed at a side of the inner plate 120 away from the evaporation hole 112, that is, the outer plate 130 is disposed at an outer side of the inner plate 120; the driving device 140 is connected to the outer plate 130; the outer plate 130 is configured to limit an evaporation range of the evaporation source 110; the driving device 140 is configured to adjust the evaporation range of the evaporation source 110. In this way, the evaporation apparatus can adjust the evaporation range of the evaporation source by driving the outer plate through the driving device so as to adjust the evaporation rate of the evaporation apparatus. By adjusting the evaporation rate of the evaporation apparatus, the thickness of the film layer to be formed by evaporation can be adjusted, so as to realize a quick adjustment of the thickness of the film layer to be formed by evaporation, thereby improving the production efficiency. In addition, as illustrated in FIG. 3, the film thickness detector 128 is partly disposed inside the inner plate 120, that is, the film thickness detector 128 is embedded inside the inner plate 120; moreover, the electrical circuit 126 connected to the film thickness detector 128 is also disposed inside the inner plate 120. In this way, the evaporation apparatus can prevent the above-mentioned electrical circuit from any damage resulted by baking under high temperature and sticking of evaporated material, so as to enhance a stability of the evaporation apparatus and improve the service life of the evaporation apparatus. Additionally, as illustrated in FIG. 3, the evaporation apparatus is further provided with a cooling device for cooling the film thickness detector. In this way, the evaporation apparatus can cool the film thickness detector through the cooling device, which on one hand can avoid an excessively high temperature of the film thickness detector so as to improve the detecting precision of the film thickness detector, and on the other hand can provide the film thickness detector with a protection function so as to extend the service life of the film thickness detector.

For example, as illustrated in FIG. 3, the at least one evaporation hole 112 can include a plurality of evaporation holes 112 which are arranged in a line on the evaporation source 110. In this way, an evaporation process over a large area can be achieved by using the plurality of evaporation holes arranged in a line, so as to improve a uniformity of evaporation.

For example, as illustrated in FIG. 3, the evaporation apparatus can include a plurality of film thickness detectors 128; the plurality of film thickness detectors 128 can be disposed in one-to-one correspondence with the plurality of evaporation holes 112, so as to detect evaporation rates at locations of different evaporation holes 112.

An embodiment of the present disclosure provides an evaporation apparatus. FIG. 4 is a structural diagram of another evaporation apparatus provided by an embodiment of the present disclosure. Unlike the preceding embodiment, as illustrated in FIG. 4, in the present evaporation apparatus, the driving device 140 includes a rotating device 145; the outer plate 130 includes a main body part 1301 and a rotating part 1302. The main body part 1301 is disposed at a side of the inner plate 120 away from the evaporation hole 112; the main body part 1301 and the inner plate 120 both extend along a direction parallel to a center line (as illustrated in FIG. 4) of the evaporation hole 112; an end 1300 of the main body part 1301 away from the evaporation source 110 extends beyond an end 1200 of the inner plate 120 away from the evaporation source 110; an end of the rotating part 1302 is hinged with the end 1300 of the main body part 1301 away from the evaporation source 110 through a pivot, for example; the rotating device 145 is configured to drive the rotating part 1302 to rotate towards a direction close to the evaporation source 110. For example, as illustrated in FIG. 4, the rotating device 145 is disposed at a location where an end of the rotating part 1302 is hinged with the end 1300 of the man body part 1301 away from the evaporation source 110, so as to drive the rotating part 1302 to rotate towards a direction close to the evaporation source 110 and a direction away from the evaporation source 110. Of course, the embodiments of the present disclosure include but are not limited thereto, and the rotating device can also be disposed at other locations, as long as the rotating part can be driven towards a direction close to the evaporation source and a direction away from the evaporation source.

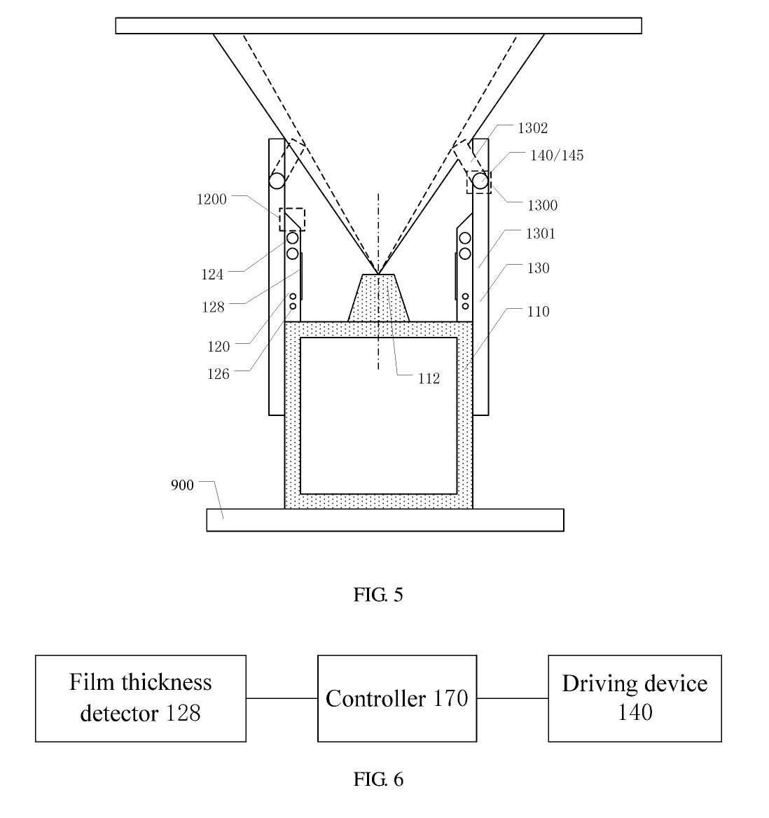

FIG. 5 is a working principle diagram of an evaporation apparatus provided by an embodiment of the present disclosure. As illustrated in FIG. 5, when the rotating part 1302 rotates towards the direction (as indicated by the dashed line in FIG. 5) close to the evaporation source 110, the evaporation range of the evaporation source 110 is narrowed. Similarly, when the rotating part rotates towards the direction away from the evaporation source, the evaporation range of the evaporation source is expanded. In this way, the evaporation range of the evaporation source can be adjusted by driving the rotating part to rotate towards a direction close to the evaporation source and a direction away from the evaporation source, so as to adjust the evaporation rate of the evaporation apparatus.

It should be noted that, the driving device can also include both of the lifting device and the rotating device to drive the outer plate to perform ascending and descending movement and drive the rotating part to rotate, so as to jointly adjust the evaporation range of the evaporation source.

For example, FIG. 6 is a schematic diagram illustrating a connecting relationship of a controller in an evaporation apparatus provided by an embodiment of the present disclosure. As illustrated in FIG. 6, the evaporation apparatus further includes a controller 170 which is communicatively connected to the film thickness detector 128 and the driving device 140, respectively, by wires or wireless communication means (e.g., Wi-Fi), for example. The controller 170 can control the driving device 140 according to the evaporation rate detected by the film thickness detector 128. In this way, the controller can obtain the thickness of the evaporated film layer evaporated on the substrate to be evaporated just by obtaining the evaporation rate of the evaporation apparatus. When it needs to adjust the thickness of the evaporated film layer evaporated on the substrate to be evaporated, the controller can control the driving device to drive the outer plate directly according to the current evaporation rate detected by the film thickness detector, so as to change the evaporation rate. For example, it can drive the rotating part of the outer plate in the direction close to the evaporation source, by the rotating device of the driving device, until the current evaporation rate detected by the film thickness detector equaling to the desired evaporation rate.

The following statements should be noted:

(1) The accompanying drawings of the embodiments of the present disclosure involve only the structure(s) in connection with the embodiment(s) of the present disclosure, and other structure(s) can be referred to common design(s).

(2) In case of no conflict, features in one embodiment or in different embodiments of the present disclosure can be combined.

The foregoing are merely specific embodiments of the invention, but not limitative to the protection scope of the invention. Within the technical scope disclosed by the present disclosure, any alternations or replacements which can be readily envisaged by one skilled in the art shall be within the protection scope of the present disclosure. Therefore, the protection scope of the invention shall be defined by the accompanying claims.

1. An evaporation apparatus, comprising:
an operation platform;
an evaporation source on the operation platform;
an inner plate on at least one side of the evaporation source, being configured to measure an evaporation rate of the evaporation source and fixedly connected to the evaporation source; and
an outer plate on a side of the inner plate away from the evaporation source, being adjacent to the inner plate and configured to adjust an evaporation range.

2. The evaporation apparatus according to claim 1, wherein the inner plate and the outer plate are at two opposite sides of the evaporation source, respectively.

3. The evaporation apparatus according to claim 1, further comprising a driving device, wherein the driving device is connected to the outer plate and is configured to drive the outer plate so as to adjust the evaporation range.

4. The evaporation apparatus according to claim 3, wherein the driving device comprises a lifting device, the lifting device is configured to drive the outer plate to move along a direction away from the operation platform so as to change a height of the outer plate with respect to the operation platform.

5. The evaporation apparatus according to claim 3, wherein the driving device comprises a rotating device,
the outer plate comprises:
a main body part at a side of the inner plate away from the evaporation source, the main body part and the inner plate both extend along a direction perpendicular to the operation platform, an end of the main body part away from the evaporation source extends beyond an end of the inner plate away from the evaporation source; and
a rotating part, an end of the rotating part is hinged with the end of the main body part away from the evaporation source,
wherein the rotating device is configured to drive the rotating part towards a direction close to the evaporation source and a direction away from the evaporation source.

6. The evaporation apparatus according to claim 1, further comprising:
a film thickness detector at least partly disposed inside the inner plate,
wherein the film thickness detector is configured to detect an evaporation rate of the evaporation apparatus.

7. The evaporation apparatus according to claim 6, wherein the film thickness detector comprises a piezoelectric sensor.

8. The evaporation apparatus according to claim 6, further comprising a controller, wherein
the controller is communicatively connected to the film thickness detector and the driving device, respectively, and is configured to control the driving device according to the evaporation rate detected by the film thickness detector.

9. The evaporation apparatus according to claim 6, further comprising a cooling device,
wherein
the cooling device is disposed inside the inner plate and is configured to cool the film thickness detector.

10. The evaporation apparatus according to claim 9, wherein the cooling device comprises a cooling liquid pipeline.

11. The evaporation apparatus according to claim 6, further comprising:
an electrical circuit disposed inside the inner plate and connected to the film thickness detector.

12. The evaporation apparatus according to claim 11, wherein the electrical circuit comprises at least one of a power supply line and a signal transmission line.

13. The evaporation apparatus according to claim 1, wherein a first surface of the inner plate facing the outer plate is disposed to be in contact with a second surface of the outer plate facing the inner plate.

14. The evaporation apparatus according to claim 1, wherein an end of the inner plate away from the evaporation source comprises a first inclined surface biased to a side of the inner plate close to the evaporation source.

15. The evaporation apparatus according to claim 1, wherein an end of the outer plate away from the evaporation source comprises a second inclined surface biased to a side of the outer plate close to the evaporation source.

16. The evaporation apparatus according to claim 1, wherein the evaporation source comprises a plurality of evaporation holes, the plurality of evaporation holes are arranged in a line on the evaporation source.

17. The evaporation apparatus according to claim 6, wherein the evaporation source comprises a plurality of evaporation holes, the plurality of evaporation holes are arranged in a line on the evaporation source,
the evaporation apparatus comprises a plurality of film thickness detectors, the plurality of film thickness detectors are disposed in one-to-one correspondence with the plurality of evaporation holes.
